(19) United States
(12) Patent Application Publication
(10) Pub. No.: US 2012/0273940 A1
(43) Pub. Date: Nov. 1, 2012

(54) SEMICONDUCTOR APPARATUS AND METHOD FOR FABRICATING THE SAME

(75) Inventor: Seung Hee JO, Seongnam-si (KR)

(73) Assignee: HYNIX SEMICONDUCTOR INC., Icheon-si (KR)

(21) Appl. No.: 13/336,948

(22) Filed: Dec. 23, 2011

(30) Foreign Application Priority Data
Apr. 29, 2011 (KR) 10-2011-0040906

(51) Int. Cl. H01L 23/498; H01L 21/78

(52) U.S. Cl. 257/737; 257/774; 438/113; 257/E23.067; 257/E23.068; 257/E21.599

(57) ABSTRACT

A semiconductor apparatus includes a first chip comprising a first bonding pad and a dielectric layer exposes a portion of the first bonding pad; a first bonding layer covering entirely or partially the first front side of the first chip, a second chip comprising a second bonding pad and a through-silicon via, and a conductive projection formed over the second bonding pad. The dielectric layer is formed on of the first chip, a second back side of the second chip is bonded to the first front side of the first chip by the medium of the first bonding layer, and the second bonding pad formed on a second front side of the second chip is coupled to the first bonding pad by the through-silicon via.

### CROSS-REFERENCES TO RELATED APPLICATIONS

The present application claims priority under 35 U.S.C 119(a) to Korean Application No. 10-2011-0040906, filed on Apr. 29, 2011, in the Korean Intellectual Property Office, which is incorporated herein by reference in its entirety.

### BACKGROUND

Exemplary embodiments of the present invention relate generally to a semiconductor apparatus and a method for fabricating the same, and more particularly, to a semiconductor apparatus and a method for fabricating the same, which can easily realize a flip chip package.

With various semiconductor technologies related to miniaturization, high memory capacity, high speed operation and heat dissipation, packaging is a one of the key technology. It is because the performance of a semiconductor is determined not by the performance of the semiconductor itself but by packaging and resultant electrical connection. Actually, a large portion of delay of electrical signals in an electronic appliance operating at a high speed is induced due to package delay occurring between chips. In order to minimize the package delay, semiconductor packaging technologies have been developed from a TSOP (thin small outline package) via a BGA (ball grid array) package and a CSP (chip size package) to a flip chip package.

In the flip chip package, it is difficult to stack a plurality of chips. Also, it is difficult to stack different kinds of chips, and reduce the thickness of the flip chip package.

### SUMMARY

Embodiments of the present invention relate to a semiconductor apparatus and a method for fabricating the same, which can stack chips and can realize a flip chip package with a reduced thickness.

In an embodiment of the present invention, a semiconductor apparatus includes: a first chip formed over a first front side thereof with first bonding pads and a dielectric layer which exposes portions of the first bonding pads; a first bonding layer covering entirely or partially the first front side of the first chip; a second chip having a second back side which is bonded with the first front side of the first chip by the medium of the first bonding layer and a second front side over which second bonding pads are present, and formed with through-silicon vias which electrically connect the first bonding pads and the second bonding pads with each other; and conductive projections formed over the second bonding pads and projecting out of the second front side.

The first bonding layer may include a silicon oxide layer, a surface activated layer, a paste layer or a polymer layer.

In detail, The silicon oxide layer may have a silicon oxide layer pattern constituted by a plurality of silicon oxide layer projections which are separated from one another, the paste layer may have a plurality of paste projections which are separated from one another or a stripe pattern which includes lines and spaces, and the polymer layer may include BCB (benzocyclobutene), PAE (poly arylene ether), PBO(polyp-phenylenebenzobioxazole) or epoxy.

The through-silicon vias may connect the first bonding pads with lowermost wiring lines among circuit patterns with a multi-layered structure which are present over the second wafer, and the circuit patterns may be electrically connected with the second bonding pads.

The conductive projections may include copper pillar bumps which are constituted by copper pillars and solder bumps stacked over the copper pillars.

In an embodiment of the present invention, a semiconductor apparatus includes: a substrate; a third chip having a third front side which is flip-chip bonded toward the substrate; a first chip having a first front side over which first bonding pads are present and a first back side which faces away from the first front side and is bonded with a third back side of the third chip; a second chip having a second back side which is bonded with the first front side of the first chip by the medium of a first bonding layer and a second front side which faces away from the second back side and over which second bonding pads are present; bonding wires connected to the second bonding pads and wire bonding pads of the substrate; and through-silicon vias connecting the first bonding pads with circuit patterns which are formed over the second front side of the second chip, and passing through the second chip.

The third chip may include a baseband processing unit, and the first chip and the second chip may include a storage unit.

The third chip may include a DRAM chip, the first chip and the second chip may include flash memory chips, and the semiconductor apparatus may further include a flash memory controller which is stacked over the second chip.

In an embodiment of the present invention, a method for fabricating a semiconductor apparatus includes: forming, on a first front side of a first wafer having the first front side and a first back side facing away from the first front side, a semiconductor device, circuit patterns for applying electrical signals to the semiconductor device, and first bonding pads which are connected with the circuit patterns; preparing a second wafer with a via middle structure or a via first structure, having a second front side and a second back side facing away from the second front side; bonding the second back side of the second wafer with the first front side of the first wafer; forming through-silicon vias which pass through the second wafer and are connected with the first bonding pads; and forming, on the second front side of the second wafer, circuit patterns which are connected with the through-silicon vias and second bonding pads which are electrically connected with the circuit patterns.

Before the bonding of the second back side of the second wafer with the first front side of the first wafer, the method may further include removing a partial thickness of the second back side of the second wafer.

The removing of the partial thickness of the second back side of the second wafer may include: grinding the second back side of the second wafer; and performing dry-etching, wet-etching or chemical mechanical polishing for the second back side of the second wafer.

The bonding of the second back side of the second wafer with the first front side of the first wafer may be implemented through oxide-to-oxide bonding, surface activated bonding, bonding by the medium of a paste layer or bonding by the medium of a polymer layer.

In detail, the oxide-to-oxide bonding may include: forming a silicon oxide layer pattern constituted by projections which are separated from one another, over the second back side of the second wafer through a thermal oxidation process; wet-etching the second back side of the second wafer using BHF or RCA; and contacting the second back side of the second wafer with the first front side of the first wafer and then implementing heating to a temperature of 200° C. to 800° C. The bonding by the medium of the paste layer may include: applying a dielectric paste to the first front side of the first wafer or the second back side of the second wafer, into a paste pattern constituted by projections separated from one another or a stripe pattern; contacting the first front side of the first wafer and the second back side of the second wafer with each other by the medium of the dielectric paste; and setting the dielectric paste. The bonding by the medium of the polymer layer may include: coating a thermosetting polymer containing BCB, PAE, PBO or epoxy, to the first front side of the first wafer or the second back side of the second wafer; baking the first wafer or the second wafer coated with the thermosetting polymer; raising a temperature of the first wafer or the second wafer coated with the thermosetting polymer to a curing temperature of the polymer; and pressing the first wafer and the second wafer with each other.

After the forming, on the second front side of the second wafer, the circuit patterns which are connected with the through-silicon vias and the second bonding pads which are electrically connected with the circuit patterns, the method may further include forming conductive projections which are connected with the second bonding pads of the second wafer.

After the forming, on the second front side of the second wafer, the circuit patterns which are connected with the through-silicon vias and the second bonding pads which are electrically connected with the circuit patterns, the method may further include: preparing a third wafer having a third front side on which a semiconductor device, circuit patterns for applying electrical signals to the semiconductor device and third bonding pads connected with the circuit patterns are formed; and bonding a third back side of the third wafer facing away from the third front side with the first back side of the first wafer.

After the bonding of the third back side of the third wafer facing away from the third front side with the first back side of the first wafer, the method may further include: sawing the third wafer, the first wafer and the second wafer which are sequentially stacked and thereby forming a third chip, a first chip and a second chip; facing the third front side of the third wafer toward a substrate and flip-chip bonding the third front side of the third wafer to the substrate; and wire bonding the second chip with the substrate.

### BRIEF DESCRIPTION OF THE DRAWINGS

The above and other aspects, features and other advantages will be more clearly understood from the following detailed description taken in conjunction with the accompanying drawings, in which:

FIG. 1 is a cross-sectional view illustrating the schematic configuration of a first wafer in accordance with an embodiment of the present invention;

FIGS. 2a and 2b are cross-sectional views illustrating the schematic configuration of a second wafer in accordance with an embodiment of the present invention;

FIG. 3 is a cross-sectional view illustrating a state in which a portion of the back side of the second wafer is removed so as to reduce the thickness of the wafer;

FIGS. 4a to 4c are views explaining an exemplary embodiment of oxide-to-oxide bonding;

FIG. 5 is a view explaining surface activated bonding;

FIG. 6a is a cross-sectional view explaining an exemplary embodiment of bonding by the medium of paste;

FIGS. 6b to 6e are plan views of FIG. 6a;

FIG. 7 is a cross-sectional view illustrating a state in which the first wafer and the second wafer are bonded with each other;

FIG. 8 is a cross-sectional view illustrating a state in which a through hole is formed through the second wafer after the first wafer and the second wafer are bonded with each other;

FIG. 9 is a cross-sectional view illustrating a state in which a through-silicon via is formed;

FIG. 10 is a cross-sectional view illustrating a state in which a BEOL process is completed after forming the through-silicon via;

FIG. 11 is a cross-sectional view illustrating a state in which a conductive projection is formed;

FIG. 12 is a cross-sectional view illustrating a flip chip package in accordance with an embodiment of the present invention;

FIG. 13 is a cross-sectional view explaining a semiconductor apparatus and a method for fabricating the same in accordance with an embodiment of the present invention;

FIG. 14 is a cross-sectional view illustrating a semiconductor apparatus in accordance with an embodiment of the present invention;

FIG. 15 is a block diagram illustrating the schematic configuration of a semiconductor apparatus (a communication module) in accordance with an embodiment of the present invention; and

FIG. 16 is a cross-sectional view illustrating a semiconductor apparatus in accordance with an embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention. In the drawings, the thicknesses of films (layers) and regions may be exaggerated for the sake of clear illustration.

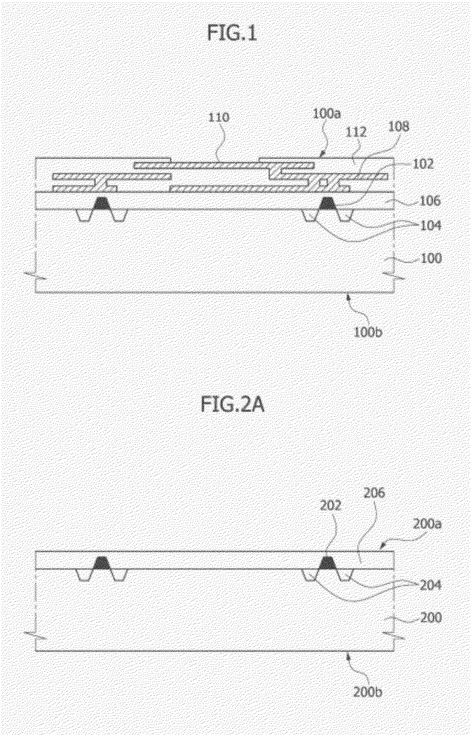

A semiconductor apparatus and a method for fabricating the same in accordance with embodiments of the present invention will be described with reference to FIGS. 1 to 12.

FIG. 1 is a cross-sectional view illustrating the schematic configuration of a first wafer in accordance with an embodiment of the present invention. Referring to FIG. 1, a first wafer 100 having a front side (hereinafter, referred to as a ‘first front side’) 100a and a back side (hereinafter, referred to as a ‘first back side’) 100b facing away from the first front side 100a is prepared. The first wafer 100 may be a wafer for fabricating a semiconductor memory device, a logic device, an optical device, or a display device. While the following descriptions will be given with respect to processes for fabricating a memory device on the silicon wafer 100 unless otherwise stated, it is to be noted that the key idea of the present invention may be applied to fabrication of other devices and other semiconductor apparatuses.

In some embodiments of the present invention, a ‘front side’ indicates a surface on which a semiconductor device such as an active device and a passive device is formed (that is, a surface on which an active region is present), and a ‘back side’ indicates a surface opposite to the front side. When the term, the front side or the back side, is used, it may represent the surface of a wafer itself. In the case of a semiconductor device, if various layers such as a dielectric layer and a conductive layer are formed on the surface of the semiconductor device, the term such as the front side or the back side may indicate the semiconductor device, the dielectric layer, or the conductive layer.

Transistors comprising gates 102 and sources/drains 104 may be formed on the first front side 100a of the first wafer 100. Besides, capacitors (not shown), an interlayer dielectric layer 106, various circuit patterns such as bit lines and word lines for applying electrical signals to the gates 102 and the sources/drains 104, and a dielectric layer 112, which constitute memory devices, may be formed. Pads (hereinafter, referred to as ‘first bonding pads’) 110 may be formed to be electrically connected to an external device such as an external circuit board. Consequently, the first wafer 100 may be a fab-out wafer which has completely undergone various processes from an FEOL (front-end-of-line) process to a BEOL (back-end-of-line) process and is formed with various semiconductor devices and wiring lines. For the sake of convenience in explanation, the first wafer 100 is simply shown in FIG. 1.

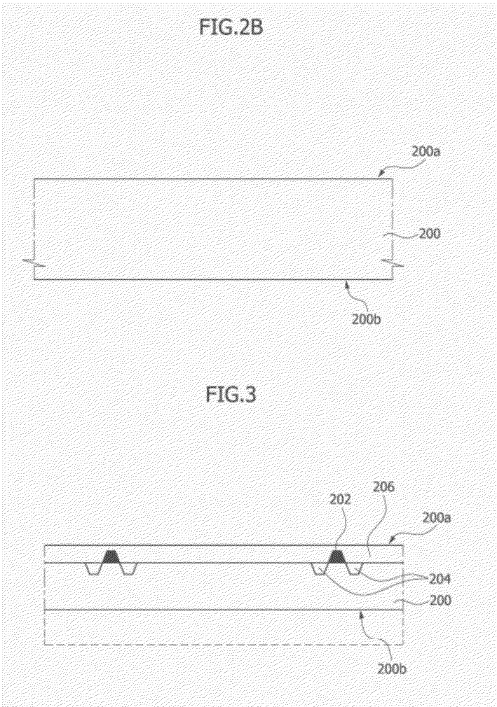

FIGS. 2a and 2b are cross-sectional views illustrating the schematic configuration of a second wafer in accordance with an embodiment of the present invention. Referring to FIGS. 2a and 2b, a second wafer 200 having a front side (hereinafter, referred to as a ‘second front side’) 200a and a back side (hereinafter, referred to as a ‘second back side’) 200b facing away from the second front side 200a is prepared. The second wafer 200 may be a wafer for fabricating a semiconductor memory device, a logic device, an optical device, or a display device. While the following descriptions will be given with respect to processes for fabricating a memory device on the silicon wafer 200 unless otherwise stated, it is to be noted that the key idea of the present invention may be applied to fabrication of other devices and other semiconductor apparatuses.

Processing technologies for a 3D integrated circuit using through-silicon vias (TSVs) may be divided into a via first technology, a via middle technology and a via last technology, depending upon when the through-silicon vias are formed. In the via first technology, after through-silicon vias are formed, the FEOL (front-end-of-line) process for forming various components such as transistors and contact plugs are performed. In the via middle technology, after the FEOL process is performed, via holes are formed, through-silicon vias are formed by filling the via holes with a conductive material, and then the BEOL (back-end-of-line) process is performed. In the via last technology, through-silicon vias are formed in a wafer which have completely undergone the FEOL process and the BEOL process.

In an embodiment of the present invention, the second wafer 200 may be a wafer which has a via middle structure or a via first structure. In an embodiment of the present invention, a wafer with a via middle structure may be a wafer which has undergone the FEOL process before a through-silicon via forming process and the BEOL process are performed, a wafer with a via first structure may be a wafer which does not have undergone the through-silicon via forming process and the BEOL process, and a wafer with a via last structure may be a wafer which has completely undergone the FEOL process and the BEOL process.

Referring to FIG. 2a, transistors comprising gates 202 and sources/drains 204 and a dielectric layer 206 may be formed on the second front side 200a of the second wafer 200. The second wafer 200 may be a via middle structure which has undergone various processes before forming metal lines. That is to say, the second wafer 200 may be a wafer which has undergone the FEOL process. For example, the second wafer 200 may be a wafer in which an isolation structure (such as trenches and LOCOS), wells (n wells and p wells), a gate oxide layer, gate electrodes, spacers, capacitors, sources/drains, an interlayer dielectric layer before wiring and contact plugs are formed. However, it is not necessary for the entire above-described processes to be inevitably performed, and instead, some processes may be omitted or added or a process sequence may be changed depending upon a fabrication purpose. The second wafer 200 shown in FIG. 2b is a wafer with the via first structure, that is, a wafer before performing the FEOL process.

Therefore, in an embodiment of the present invention, the second wafer 200 may be a wafer with the via first structure or the via middle structure. Hereinbelow, unless specifically stated, descriptions will be given on the assumption that the second wafer 200 has the via middle structure.

FIG. 3 is a cross-sectional view illustrating a state in which a partial thickness of the back side of the second wafer is removed, that is, a state in which a portion of the back side of the second wafer is removed so as to reduce the thickness of the wafer. Referring to FIG. 3, after removing a portion of the second back side 200b of the second wafer 200, the second back side 200b of the second wafer 200 is attached to the first front side 100a of the first wafer 100.

A process for removing the portion of the second back side 200b may be performed by two separate thinning processes, that is, a primary thinning process and a secondary thinning process. The primary thinning process is a process for decreasing the thickness of a wafer by a substantial amount and may be performed through mechanical back-grinding. The secondary thinning process is a process for decreasing the roughness of the surface of the wafer and alleviating the physical damage to the wafer resulting from the grinding process, and may be performed through dry etching, wet etching or chemical mechanical polishing (CMP). Dry etching may be performed using SF₆, and wet etching may be performed using a TMAH (Tetramethylammonium hydroxide) or potassium hydroxide (KOH) solution. While the processing condition of chemical mechanical polishing is not specifically limited, chemical mechanical polishing may be performed using 0.1˜0.5 μm of silica slurry with a pH value of 9˜11.

After the primary and second thinning processes are performed, the first front side 100a of the first wafer 100 and the second back side 200b of the second wafer 200 are bonded to each other. A method for bonding the first wafer 100 and the second wafer 200 is not specifically limited. For example, oxide-to-oxide bonding, surface activated bonding (SAB), bonding by the medium of paste or bonding by the medium of polymer coupling may be used.

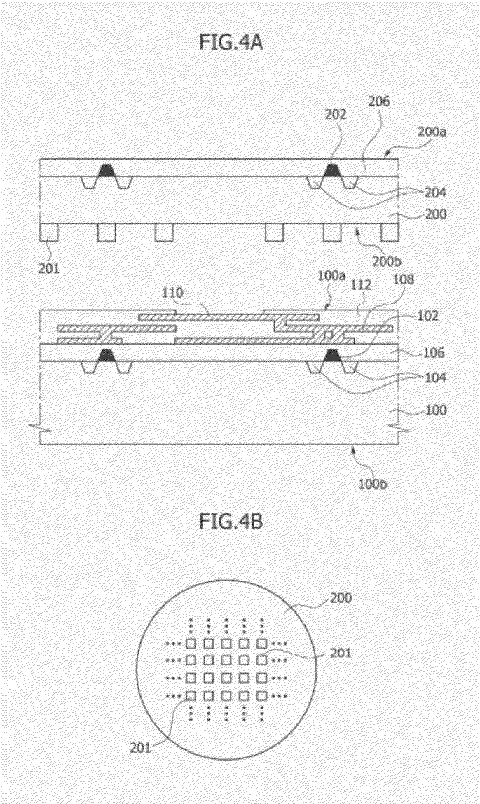

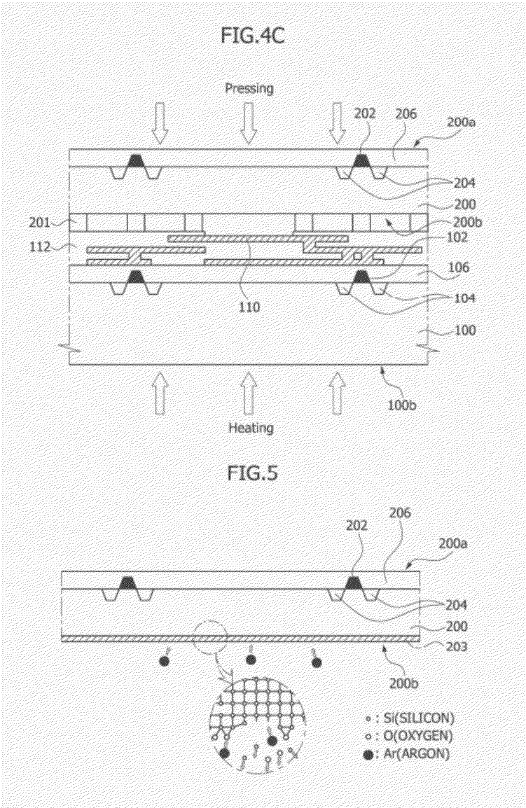

FIGS. 4a to 4c are views explaining an exemplary embodiment of oxide-to-oxide bonding.

Referring to FIG. 4a, in order to form an oxide-to-oxide bonding, a silicon oxide layer SiOx is formed on the second back side 200b of the second wafer 200 through a thermal oxidation process and is patterned through a lithographic process. By the processes described above, a silicon oxide layer pattern having silicon oxide layer projections 201 separated from one another may be formed. On the other hands, a silicon oxide layer may be formed to cover the entire second back side 200b of the second wafer 200 such that bonding is implemented by the medium of the silicon oxide layer without the lithographic process. By forming the silicon oxide layer pattern having the projections 201 separated from one another, a probability that the wafer is broken or cracked by a pressure applied when bonding process is subsequently performed decreases. The thickness of the silicon oxide layer is not specifically limited and may be several tens nanometers to several hundreds nanometers. Also, the diameter of the silicon oxide layer projections 201 constituting the silicon oxide layer pattern is not specifically limited and may be several micrometers to several hundreds micrometers.

The dielectric layer 112 formed on the first wafer 100 may be a silicon oxide layer SiOx. That is to say, the dielectric layer 112 may be used in bonding. Otherwise, another silicon oxide layer may be additionally formed on the dielectric layer 112.

The shape of the silicon oxide layer pattern (the arrangement of the silicon oxide layer projections) is not specifically limited. For example, as shown in FIG. 4b, the silicon oxide layer projections may be regularly arranged in transverse and longitudinal directions. Besides, an irregular arrangement may be adopted.

After forming the silicon oxide layer pattern, the second back side 200b of the second wafer 200 formed with the silicon oxide layer pattern may be wet-etched (wet-cleaned). While BHF (buffered HF) or RCA may be used as an etching solution for wet etching, an etching solution (a cleaning solution) is not specifically limited. RCA is a mixed solution of DI (deionized water), hydrogen peroxide (H₂O₂), ammonium hydroxide (NH₄OH) and hydrochloric acid (HCl). By the wet etching, the effective area of the silicon oxide layer pattern to be bonded may be increased, and the surface of the silicon oxide layer pattern may be kept clean. Further, the surface of the silicon oxide layer pattern may be made hydrophilic so that a bonding force increases, and bonding may be implemented at a lower temperature.

Referring to FIG. 4c, the second back side 200b of the second wafer 200 on which the silicon oxide layer pattern is formed and the dielectric layer 112 formed on the first front side 100a of the first wafer 100 may be brought into contact with each other and may be bonded to each other through heating and pressing. Although the bonding may be implemented at a room temperature, a bonding force may be poor. Therefore, heat may be applied to increase the bonding force. A heating temperature is not specifically limited, and for example, may be 200° C. to 800° C. While it is of course possible to raise a temperature over 800° C., bonding may be implemented at as low a temperature as possible so as to prevent the characteristics of a semiconductor device formed previously from deteriorating and to implement bonding at a reduced cost. The first wafer 100 and the second wafer 200 may be heated and pressed in a state in which they are placed on jigs. Pressing may be performed with a pressure of several KPa to several MPa.

FIG. 5 is a view explaining a surface activated bonding. In the surface activated bonding, a surface is activated before bonding so that the inherent cohesive energy of a solid surface is used as bonding energy. The surface activation bonding is implemented in such a way as to make a surface unstable through FAB (fast atom beam) bombardment or ion beam bombardment using an inert gas such as argon (Ar). Besides, plasma radiation or radical radiation may be used. An atom beam with energy of 1˜5 eV may be used, and a large current ion beam of several tens eV may be used. In plasma radiation or radical radiation, DC plasma, RF plasma, and radical radiation under an RIE mode may be used.

As can be readily seen from the drawing, if an atom beam is radiated to the second back side 200b, a native oxide layer formed on the surface is removed, and bonds between silicon and silicon are broken, and thus a surface activated layer 203 with an unstable state is generated. In order to form the surface activated bonding, the first front side 100a of the first wafer to be bonded with the second back side 200b may include silicon. Accordingly, it may be more effective that an amorphous silicon layer or a polysilicon is formed on the dielectric layer 112 (see FIG. 1) of the first front side 100a and the above-described atom beam bombardment occurs in the same manner so that a surface activated layer is generated.

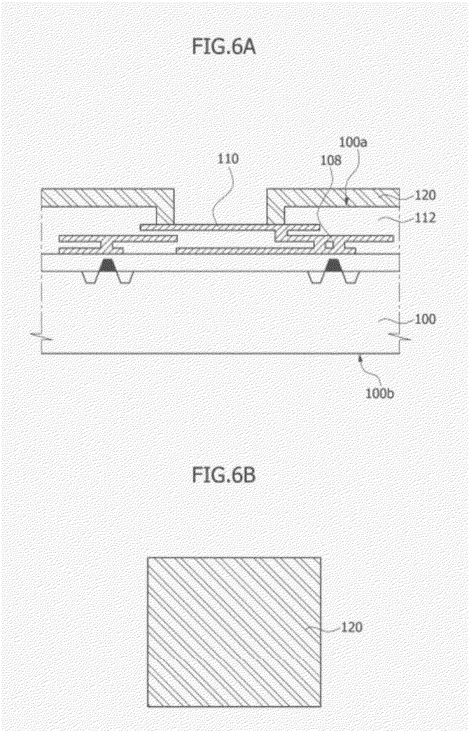

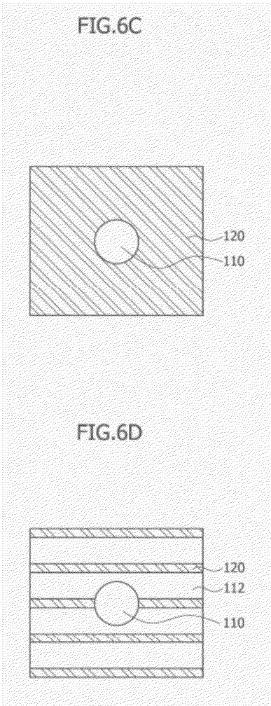

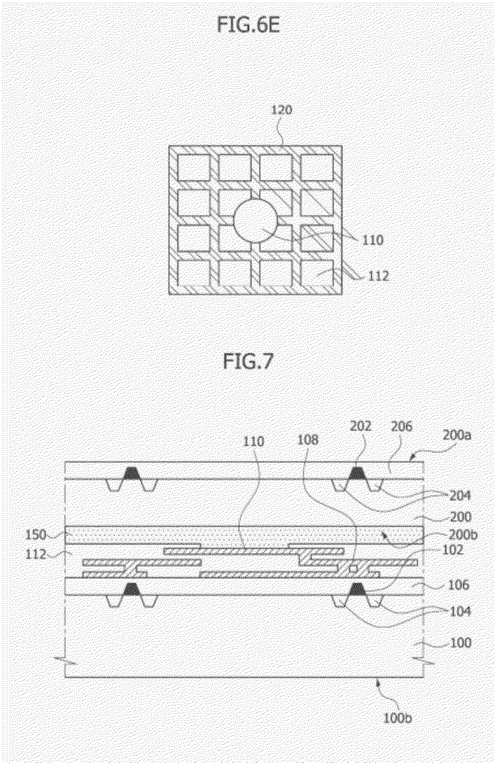

FIG. 6a is a cross-sectional view explaining an exemplary embodiment of bonding by the medium of paste, and FIGS. 6b to 6e are plan views of FIG. 6a. Referring to FIGS. 6a to 6e, the first wafer 100 and the second wafer 200 may be bonded with each other by the medium of paste.

In order to perform a bonding process by the medium of paste, a paste 120 is applied to at least one of the first front side 100a of the first wafer and the second back side 200b of the second wafer (see FIGS. 2a and 2b). Hereafter, descriptions will be made with respect to the case of applying the paste 120 to the first front side 100a of the first wafer.

The application of the paste 120 may be performed using a printing technology such as screen printing, and the paste 120 may be a dielectric paste with an electrical insulation property. The dielectric paste may include a metal oxide such as a silicon oxide, a glass frit, an organic vehicle.

The application pattern of the paste is not specifically limited. For example, the paste may be applied to entirely cover the first front side 100a (see FIG. 6b) of the first wafer, may be applied to cover the first front side 100a excluding a region where a through-silicon via is to be subsequently formed (see FIG. 6c), may be applied in a stripe pattern (including lines and spaces) excluding a region where a through-silicon via is to be subsequently formed (see FIG. 6d), or may be applied in a lattice pattern excluding a region where a through-silicon via is to be subsequently formed (see FIG. 6e). Otherwise, the paste may be applied in a shape (not shown) in which a plurality of paste projections separated from one another are repeated in the same manner as in the silicon oxide layer pattern described above. The paste may be applied to partial regions of the first front side 100a of the first wafer rather than being applied in a shape which covers the entire first front side 100a of the first wafer, to allow an organic vehicle such as a solvent to be easily discharged in subsequent processes for drying and setting the paste.

After the paste is applied, the first wafer 100 and the second wafer 200 may be brought into contact with each other and may be bonded to each other through the drying and setting processes. Before bring the first wafer 100 and the second wafer 200 into contact with each other, the process for drying the paste may be first performed.

While not shown in a drawing, the first wafer 100 and the second wafer 200 may be bonded with each other through polymer coupling. That is to say, the first wafer 100 and the second wafer 200 may be bonded to each other in such a manner that a polymer is spin-coated and interdiffusion and crosslinking reaction of the polymer occur through a baking process. Bonding through polymer coupling may be implemented through spin-coating and baking a thermosetting polymer, such as BCB (benzocyclobutene), PAE (poly arylene ether), PBO (polyp-phenylenebenzobioxazole) or epoxy, on at least one of the first front side 100a (see FIG. 1) of the first wafer and the second back side 200b (see FIGS. 2a and 2b) of the second wafer, raising a temperature up to a curing temperature (Tc) of the thermosetting polymer, and pressing the first wafer and the second wafer with each other.

FIG. 7 is a cross-sectional view illustrating a state in which the first wafer 100 and the second wafer 200 are bonded to each other by the medium of a bonding layer (hereinafter, referred to as a ‘first bonding layer’) 150. The second wafer 200 shown in FIG. 7 may be a wafer with a via middle structure or a wafer with the via first structure as described above. The first bonding layer 150 may be a silicon oxide layer, a surface activated layer, a paste layer or a polymer layer as described above.

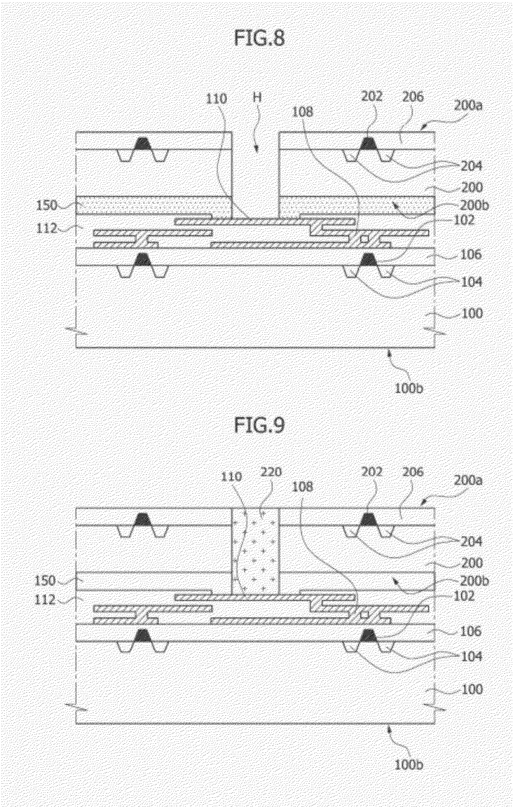

FIG. 8 is a cross-sectional view illustrating a state in which a through hole is formed through the second wafer 200. As shown in FIG. 8, after bonding the wafers, a through hole (via hole) H is formed to pass through the second wafer 200. In other words, the through hole H is formed in such a way as to pass from the upper surface of the dielectric layer 206 of the second wafer through the second wafer 200 and the first bonding layer 150 and to expose the upper surface of the first bonding pad 110. Also, as described above, a shape may be conceivable such that the first bonding layer 150 does not exist in a region where the through hole H is formed. In this case, it is not necessary to remove a portion of the first bonding layer 150 in the process for forming the through hole H. In other words, it is not necessary to remove layers formed of different materials.

A method for forming the through hole H is not specifically limited. For example, the through hole H may be formed by a DRIE (deep reactive ion etching) method or a laser etching method. The DRIE method is an etching technology using plasma, in which processes for etching silicon using SF₆ plasma and then additionally performing polymer coating using C₄F₈ plasma to induce unisotropic etching may be employed. The laser etching method is a technology for processing a metal layer at a high speed and may be adopted for a large area. Therefore, lithography and a toxic gas may not be used. As a laser for laser etching, an Nd:YAG laser, a CO₂, and the like may be used, and a laser of an ultraviolet (UV) band may also be used.

FIG. 9 is a cross-sectional view illustrating a state in which a through-silicon via is formed. Before filling the through hole H (see FIG. 8) with a conductive material, a through hole insulation layer, a barrier layer and a seed layer may be formed on the surface of the through hole H. However, depending upon a kind of material for forming a through-silicon via 220 and a filling method, at least one of the through hole insulation layer, the barrier layer and the seed layer may be omitted or another layer may be additionally formed.

The through hole insulation layer (not shown) formed on the surface of the through hole may perform an insulation function between the through-silicon via 220 and the second wafer 200. The through hole insulation layer may be formed of an insulation material including at least one of an organic insulation material and an inorganic insulation material, for example, an insulation material including a silicon oxide. The through hole insulation layer may be formed using a thin film deposition process which is generally known in the art, such as sputtering, CVD (chemical vapor deposition) and thermal oxidation, or using a coating method such as spin coating and dip coating. Preferably, a silicon oxide layer SiOx may be formed through CVD.

In the case where the through-silicon via 220 is formed through electroplating, a seed layer (not shown) may be formed before forming the through-silicon via 220. The seed layer may be formed of a metal including at least one of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr), molybdenum (Mo) and ruthenium (Ru).

A method for forming the seed layer is not specifically limited. For example, the seed layer may be formed through vacuum deposition, sputtering, chemical vapor deposition or electroless plating. In detail, a seed metal layer containing copper may be formed through electroless plating. A plating solution used in electroless copper plating includes a copper ion source, a pH regulator and a reducing agent. Besides, the plating solution may include a complexing agent and a surfactant. Here, the copper ion source may include CuSO₄.5H₂O and CuSO₄, the pH regulator may include KOH and NaOH, and the reducing agent may include formaldehyde (HCHO). Also, a catalyst such as palladium (Pd) and a compound of palladium (Pd) and tin (Sn) may be used. As a pH rises (to about pH 11 or over) by the pH regulator, reduction occurs by the reducing agent and electrons are generated. As the electrons flow to copper ions, the copper ions are precipitated on a palladium catalyst, and thus the copper seed layer may be coated. In another example, a seed metal layer formed of copper, ruthenium or tungsten may be formed through sputtering or chemical vapor deposition.

The barrier layer (not shown) is formed so as to prevent diffusion of a metallic material which will subsequently fill the through hole H. Also, the barrier layer may be used when forming the through-silicon via using copper. The barrier layer may include titanium (Ti), tantalum (Ta), tungsten (W), molybdenum (Mo) or a nitride thereof, and may be formed through chemical vapor deposition or sputtering. However, it is to be noted that the material and the forming method of the barrier layer are not specifically limited.

Thereafter, the through-silicon via 220 is formed by filling the through hole H (see FIG. 8) with a conductive material. The conductive material may include a metal including at least one of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr), molybdenum (Mo) and ruthenium (Ru), a conductive organic, and so forth. Here, the conductive material may have a shape of a single-layered film or a multi-layered film. Filling the through hole H with the conductive material may be performed using at least one method of vacuum deposition, sputtering, chemical vapor deposition, electroless plating, electroplating, dispensing and screen printing.

For example, it is possible to fill the through hole by electroplating of copper. In an example of electroplating of copper, an electroplating solution may include a copper ion source, a sulphuric acid (H₂SO₄) for regulating electrical conductivity, and a hydrochloric acid (HCl) for regulating a reduction reaction, and may further include additives. As CuSO⁴ as the copper ion source is put into the sulphuric acid (H₂SO₄) and water, CuSO⁴ is divided into Cu²⁺ ions and SO₄²⁻ ions. After the electroplating of copper, electroplating of gold may be additionally performed so as to improve electrical characteristics. In this regard, gold and copper ingredients have poor strengths and may be easily abraded, and if gold is directly plated on copper, the gold ingredient may move toward copper and the copper ingredient may move toward gold, by which the original purpose for improving electrical conductivity by gold plating may be lost. Therefore, electroplating of nickel may be performed before electroplating of gold. In a plating solution for electroplating of gold, chloroaurate or gold sulfite may be used as a gold source, a cyanide-based or non-cyanide-based compound may be added as a chelating agent. However, it is to be noted that the plating solution for electroplating of gold is not specifically limited.

In another example, tungsten and copper may be formed in the through hole H through chemical vapor deposition. Here, an MOCVD (metal organic chemical vapor deposition) method using a metal organic precursor such as Cu (hfac) may be used.

In addition, in the case where the second wafer 200 has the via first structure, the through hole H (see FIG. 8) may be filled using polysilicon or doped polysilicon in order to secure thermal and material compatibility with a subsequent process. When the through hole is filled with polysilicon, chemical vapor deposition may be used, and in this case, the above-described seed layer may be omitted.

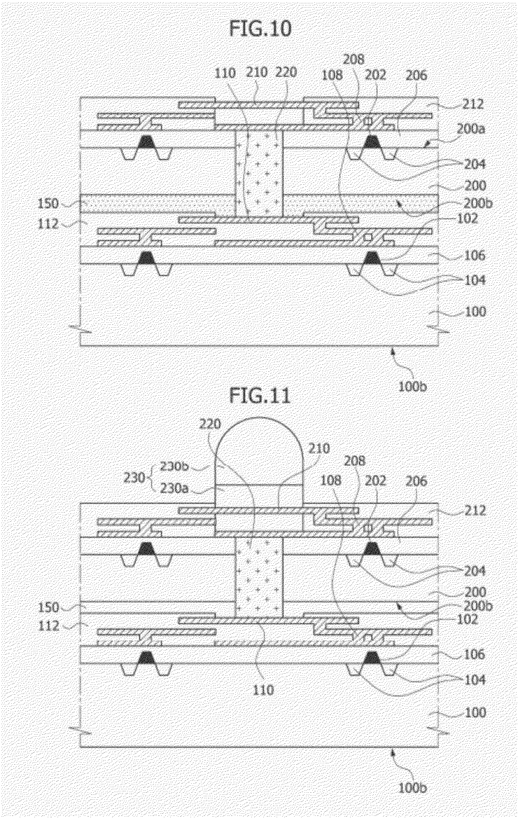

FIG. 10 is a cross-sectional view illustrating a state in which a BEOL process is completed after forming the through-silicon via. Referring to FIG. 10, circuit patterns 208 such as bit lines and word lines for transmitting electrical signals to underlying transistors, second bonding pads 210 for subsequently serving as electrical connection paths with a package substrate or a circuit board, and a dielectric layer 212 may be formed on the second front side 200a of the second wafer 200 which is formed with the through-silicon via 220. In a memory apparatus, wiring line patterns to be connected to underlying transistors may be formed in multiple layers between which dielectric layers interposed, as illustrated by the circuit patterns 208 in FIG. 10. Also, while the dielectric layer 212 may comprise a plurality of intermetal dielectrics (IMD), only one layer is shown in the drawing for convenience.

As described above, in the case where the second wafer 200 is a wafer with the via first structure, the BEOL process is performed after performing the FEOL process.

Because the second wafer 200 is a wafer with the via middle or the via first structure, the through-silicon via 220 may connect the first bonding pad 110 with the lowermost wiring line among the circuit patterns 208 with a multi-layered structure which are formed on the second wafer 200. The circuit patterns 208 may electrically connect the through-silicon via 220 with the second bonding pad 210.

FIG. 11 is a cross-sectional view illustrating a state in which a conductive projection 230 is formed on the second bonding pad 210. The conductive projection 230 is not specifically limited. For example, the conductive projection 230 may include a stud bump, a gold (Au) bump, a gold (Au)/nickel (Ni) bump or a solder bump. In the drawing, a copper pillar bump (CPB) with a solder bump 230b formed on a copper pillar 230a is illustrated. The copper pillar and the solder bump constituting the copper pillar bump may be formed through electroplating. While examples of a solder for forming the solder bump may include Sn-based, Pb-based, Au-based, In-based, Bi-based, Sn—Pb-based Sn—Ag-based, Sn—Bi-based, Sn—Pb—Ag-based and Sn—Pb—Sb-based solders, the Sn—Ag-based solder may be used. The solder bump constituting the copper pillar bump may be omitted. Also, while not shown in a drawing, a stress buffer layer, a diffusion barrier layer and a seed layer may be formed under the copper pillar of the copper pillar bump.

Thereafter, by grinding the first back side 100b of the first wafer and performing a sawing process, fabrication of a stacked package having two layers of semiconductor chips is completed.

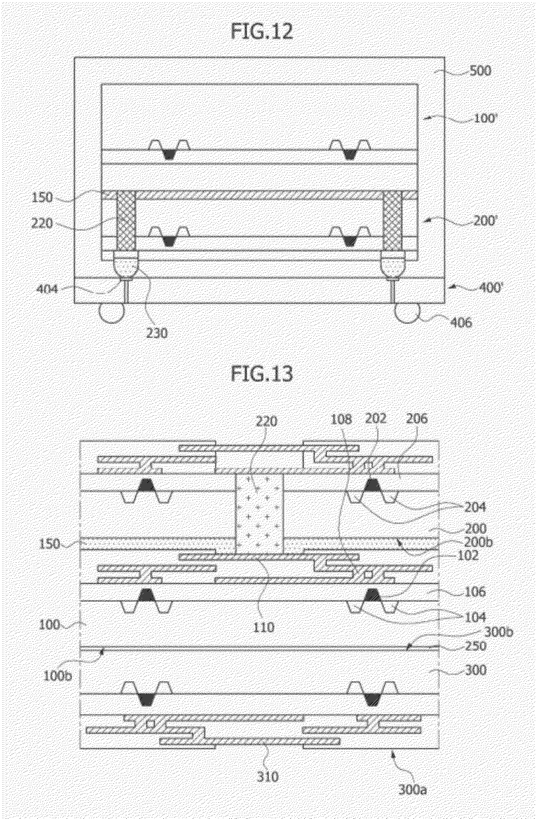

FIG. 12 is a cross-sectional view illustrating a flip chip package in accordance with an embodiment of the present invention. For the sake of convenience in explanation, a first chip 100′ and a second chip 200′ are schematically illustrated. That is to say, after sawing the stacked wafer as shown in FIG. 11, a part including the first wafer 100 (see FIG. 11) is shown as the first chip 100′, and a part including the second wafer 200 (see FIG. 11) is shown as the second chip 200′. A detailed stacking method (structure) is the same as that shown in FIG. 11.

In the flip chip package in accordance with the an embodiment of the present invention, the second front side of the second chip 200′ faces a substrate 400 such that conductive projections 230 project toward the substrate 400 and are electrically connected to flip chip bonding pads 404, and the first front side of the first chip 100′ is stacked on the second back side of the second chip 200′ by the medium of a first bonding layer 150. Through-silicon vias 220 are formed in the second chip 200′, and the conductive projections 230 are connected to the through-silicon vias 220 through circuit patterns. Solder balls 406 for electrical connection with an external device such as an external printed circuit board (PCB) may be formed on the lower surface of the substrate 400. The reference numeral 500 designates an encapsulant (for example, an epoxy molding compound).

The substrate 400 is not specifically limited so long as it electrically connects the semiconductor chips 100′ and 200′ inside the package with the external printed circuit board and functions to support the semiconductor chips 100′ and 200′. For example, a plastic substrate or a ceramic substrate may be used. In detail, the substrate 400 may be a substrate which has an epoxy core, electric wiring lines, and so forth and is made of a plastic material.

The first chip 100′ and the second chip 200′ may be the same kind of semiconductor chips or may be different kinds of semiconductor chips. For example, each of the first chip 100′ and the second chip 200′ may be a memory chip such as a DRAM, an SRAM, a flash memory, a PRAM, an ReRAM, an FeRAM and an MRAM. While descriptions have been made based on a semiconductor memory apparatus, the first chip 100′ and the second chip 200′ may be an ASIC (application specific integrated circuit), a GPU (graphic processing unit) or a CPU (central processing unit).

FIG. 13 is a cross-sectional view explaining a semiconductor apparatus and a method for fabricating the same in accordance with an embodiment of the present invention. The drawing illustrates a state in which, after a BEOL process is performed on a second wafer 200, a first back side 100b of a first wafer 100 is grinded, and then, a third back side 300b of a third wafer 300 is bonded to the first back side 100b of the first wafer 100. The third wafer 300 may be a wafer with a via last structure, that is, a wafer which has undergone an FEOL process and a BEOL process. The third back side 300b of the third wafer 300 may also be grinded before bonding. After bonding the third wafer 300, individual chips may be fabricated through a sawing process. Third bonding pads 310 may be formed on a third front side 300a of the third wafer 300. In a subsequent process, conductive bumps such as solder bumps may be formed on the third bonding pads 310 to be connected to a substrate.

Since a method for bonding the first wafer 100 and the third wafer 300, a second bonding layer 250, and semiconductor devices, circuit patterns, etc. constituting the third wafer 300 are the same as described above, detailed descriptions thereof will be omitted herein.

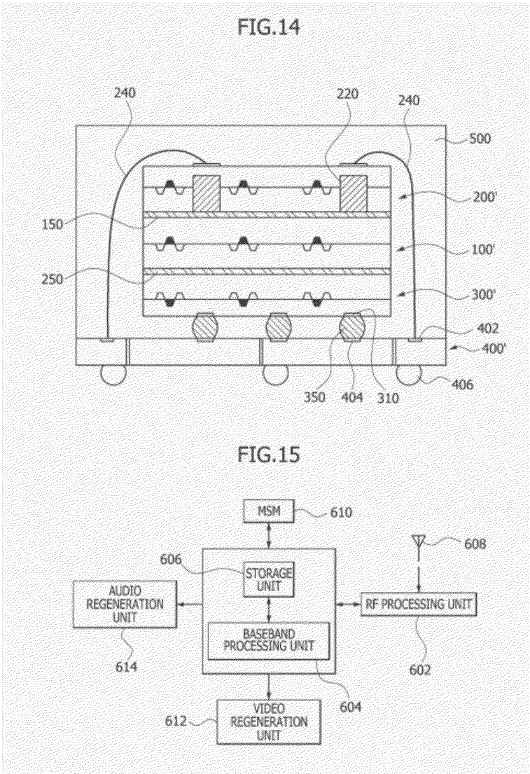

FIG. 14 is a cross-sectional view illustrating a semiconductor apparatus in accordance with an embodiment of the present invention. For the sake of convenience in explanation, a first chip 100′, a second chip 200′ and a third chip 300′ are schematically illustrated. That is to say, after sawing the stacked wafer as shown in FIG. 13, a part including the first wafer 100 (see FIG. 13) is shown as the first chip 100′, a part including the second wafer 200 (see FIG. 13) is shown as the second chip 200′, and a part including the third wafer 300 (see FIG. 13) is shown as the third chip 300′. Detailed stacking method and structure are the same as those shown in FIG. 13.

The third chip 300′ is flip-chip mounted to a substrate 400′ through conductive bumps such as solder bumps. The first back side of the first chip 100′ (corresponding to the first back side of the first wafer shown in FIG. 13) is bonded to the third back side of the third chip 300′ (corresponding to the third back side of the third wafer shown in FIG. 13), and the second back side of the second chip (corresponding to the second back side of the second wafer shown in FIG. 13) is bonded to the first front side of the first chip 100′ (corresponding to the first front side of the first wafer shown in FIG. 13).

Through-silicon vias 220 are formed in the second chip 200′. The through-silicon vias 220 may be electrically connected to wire bonding pads 402 through bonding wires 240. Third bonding pads 310 of the third chip 300′ may be connected to flip chip bonding pads 404 of the substrate 400′ through conductive bumps 350 such as solder bumps. Solder balls 406 for electrical connection with an external printed circuit board (PCB) may be formed on the lower surface of the substrate 400′. The reference numeral 500 designates an encapsulant (for example, an epoxy molding compound).

The first chip 100′, the second chip 200′ and the third chip 300′ may be the same kind of semiconductor chips or may be different kinds of semiconductor chips. For example, each of the first chip 100′, the second chip 200′ and the third chip 300′ may be an ASIC, a GPU or a CPU, or may be a memory chip such as a DRAM, an SRAM, a flash memory, a PRAM, an ReRAM, an FeRAM and an MRAM.

In detail, the third chip 300′ to be flip-chip bonded may be an ASIC, a GPU or a CPU, and each of the first chip 100′ and the second chip 200′ to be wire bonded may be an ASIC, a memory or a processor. Otherwise, all the first chip 100′, the second chip 200′ and the third chip 300′ may be memory chips. In particular, since the third chip 300′ is flip-chip bonded and thus has a high signal transmission speed, the third chip 300′ is appropriate for a high speed application. A hybrid package structure configured in this way may be used in a mobile phone such as a smart phone, a laptop computer, a camcorder, a DMB system, an MP3, a navigator and an RF transceiver system.

FIG. 15 is a block diagram illustrating the schematic configuration of a communication module as an example of a semiconductor apparatus with the configuration of FIG. 14 in accordance with an embodiment of the present invention. The following descriptions will be made based on a communication module for transmitting and receiving DMB (digital multimedia broadcasting).

Referring to FIGS. 14 and 15, the communication module may include an RF (radio frequency) processing unit 602, a baseband processing unit 604, a storage unit 606, an antenna 608, an MSM (mobile station modem) 610, a video regeneration unit 612, and an audio regeneration unit 614.

The RF processing unit 602 may include an RF section which includes a duplexer, an amplifier, a frequency synthesizer and a band pass filter (BPF), and an IF (intermediate frequency) section which includes a signal synthesizer, a signal mixer, an automatic gain controller and an amplifier. If a terrestrial DMB signal is transmitted from the antenna 608, the RF processing unit 602 selects a signal through synchronization and converts the selected signal into an intermediate frequency band signal.

The baseband processing unit 604 is linked with the storage unit 606 and generates a video signal and an audio signal from the intermediate frequency band signal. The storage unit 606 may perform a function of storing signal processing data of the baseband processing unit 604. The baseband processing unit 604 may include an ADC (analog-to-digital converter), a DAC (digital-to-analog converter), a filter, a modulator and a demodulator, and the storage unit 606 may include a memory device such as an SDRAM (synchronous DRAM).

In an embodiment of the present invention, the third chip 300′ shown in FIG. 14 serves as the baseband processing unit 604, and the first chip 100′ and the second chip 200′ shown in FIG. 14 serve as the storage unit 606. By mounting the baseband processing unit 604 and 300′ to a substrate through flip chip bonding, a package may be formed without bonding wires. As a consequence, a mounting area may be reduced, and a parasitic component coupling phenomenon between bonding wires may be prevented.

The RF processing unit 602, the baseband processing unit 604 and 300′ and the storage unit 606, 100′ and 200′ may comprise respective separate chips and may be molded into one package to be realized as a single package. The RF processing unit 602 not shown in FIG. 14 may be stacked over the storage unit 606, 100′ and 200′ or may be mounted to the substrate 400′ to be horizontally separated from the stack structure comprising the baseband processing unit 604 and 300′ and the storage unit 606, 100′ and 200′.

The MSM 610 may include a CPU and a vocoder. The MSM 610 may control operations of respective circuits, process user interface signals, and control input and output of data. The video regeneration unit 612 may convert and regenerate a video signal into an analog signal, and the audio regeneration unit 614 may regenerate an audio analog signal and output the regenerated audio analog signal through a speaker.

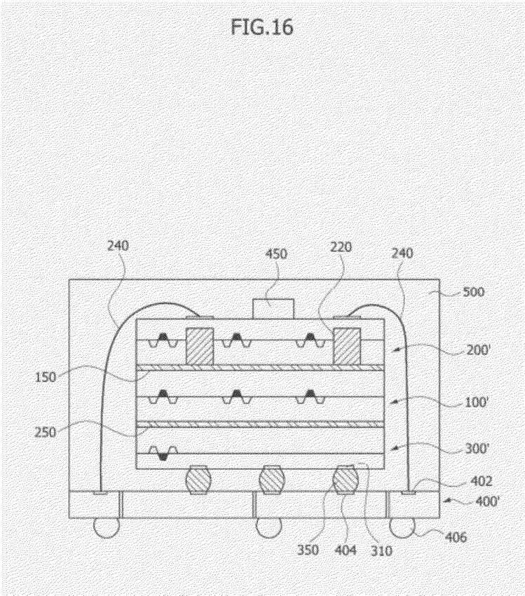

FIG. 16 is a cross-sectional view illustrating a semiconductor apparatus in accordance with an embodiment of the present invention. A flip chip package shown in FIG. 16 includes a first chip 100′, a second chip 200′, a third chip 300′ and a controller 450. The configuration of the flip chip package is the same as that shown in FIG. 14 except that the controller 450 is added.

In an embodiment of the present invention, the third chip 300′ may be a DRAM chip, and the first chip 100′ and the second chip 200′ may be flash memory chips. The controller 450 may be a flash memory controller for driving a flash memory chip. The DRAM chip 300′ which needs to operate at a high speed is connected to the substrate 400 through flip chip bonding, and the flash memory chips 100′ and 200′ which do not need to operate at a high speed are connected by bonding wires, so that a degree of freedom to realize a stacked package may be increased.

As is apparent from the above descriptions, the semiconductor apparatus and the method for fabricating the same according to the embodiments of the present invention provide flip chip packages by utilizing a via middle or via first structure, it is possible to overcome difficulties in processes which are likely to be induced due to the fact that a through-silicon via should be formed after various semiconductor apparatuses and wiring lines are formed. Also, it is possible to realize a hybrid flip chip package with a reduced thickness.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor apparatus comprising:
a first chip comprising a first bonding pad and a dielectric layer, wherein the dielectric layer formed on a first front side of the first chip exposes a portion of the first bonding pad;
a first bonding layer covering entirely or partially the first front side of the first chip;
a second chip comprising a second bonding pad and a through-silicon via, wherein a second back side of the second chip is bonded to the first front side of the first chip by the medium of the first bonding layer, and wherein the second bonding pad formed on a second front side of the second chip is coupled to the first bonding pad by the through-silicon via; and
a conductive projection formed over the second bonding pad.

2. The semiconductor apparatus according to claim 1, wherein the first bonding layer comprises one or more of a silicon oxide layer, a surface activated layer, a paste layer and a polymer layer.

3. The semiconductor apparatus according to claim 2, wherein the silicon oxide layer has a silicon oxide layer pattern comprising a plurality of silicon oxide layer projections which are separated from one another.

4. The semiconductor apparatus according to claim 2, wherein the paste layer has a plurality of paste projections which are separated from one another or a stripe pattern which includes lines and spaces.

5. The semiconductor apparatus according to claim 2, wherein the polymer layer comprises one or more of BCB (benzocyclobutene), PAE (poly arylene ether), PBO(polyp-phenylenebenzobioxazole) and epoxy.

6. The semiconductor apparatus according to claim 1, wherein the through-silicon via is configured to connect the first bonding pad with lowermost wiring lines among circuit patterns with a multi-layered structure which are formed over the second wafer, and the circuit patterns are electrically connected to the second bonding pad.

7. The semiconductor apparatus according to claim 1, wherein the conductive projection comprises a copper pillar bump comprising a copper pillar and a solder bump stacked over the copper pillar.

8. A semiconductor apparatus comprising:
a substrate;
a third chip having a third front side which is flip-chip bonded to the substrate;
a first chip having a first front side over which a first bonding pad is formed and a first back side which faces away from the first front side and is bonded to a third back side of the third chip;
a second chip having a second back side which is bonded to the first front side of the first chip by the medium of a first bonding layer and a second front side which faces away from the second back side, wherein a second bonding pad is formed over the second front side;
a bonding wire electrically connecting the second bonding pad to a wire bonding pad of the substrate; and
a through-silicon via connecting the first bonding pad to a circuit pattern formed over the second front side of the second chip, wherein the through-silicon via passes through the second chip.

9. The semiconductor apparatus according to claim 8, wherein the third chip comprises a baseband processing unit, and one or more of the first chip and the second chip comprise a storage unit.

10. The semiconductor apparatus according to claim 8,
wherein the third chip comprises a DRAM chip, the first chip and the second chip comprise flash memory chips, and
wherein the semiconductor apparatus further comprises a flash memory controller which is stacked over the second chip.

11. A method for fabricating a semiconductor apparatus, comprising:
forming, on a first front side of a first wafer having the first front side and a first back side facing away from the first front side, a semiconductor device, circuit patterns for applying electrical signals to the semiconductor device, and first bonding pads which are connected to the circuit patterns;
preparing a second wafer with a via middle structure or a via first structure, having a second front side and a second back side facing away from the second front side;
bonding the second back side of the second wafer to the first front side of the first wafer;
forming through-silicon vias which pass through the second wafer and are connected to the first bonding pads; and
forming, on the second front side of the second wafer, circuit patterns which are connected to the through-silicon vias and second bonding pads which are electrically connected to the circuit patterns.

12. The method according to claim 11, wherein, before the bonding of the second back side of the second wafer with the first front side of the first wafer, the method further comprises:
removing a partial thickness of the second back side of the second wafer.

13. The method according to claim 12, wherein the removing of the partial thickness of the second back side of the second wafer comprises:
grinding the second back side of the second wafer; and
performing dry-etching, wet-etching or chemical mechanical polishing for the second back side of the second wafer.

14. The method according to claim 11, wherein the bonding of the second back side of the second wafer with the first front side of the first wafer is implemented through oxide-to-oxide bonding, surface activated bonding, bonding by the medium of a paste layer or bonding by the medium of a polymer layer.

15. The method according to claim 14, wherein the oxide-to-oxide bonding comprises:
forming a silicon oxide layer pattern comprising projections which are separated from one another, over the second back side of the second wafer through a thermal oxidation process;
wet-etching the second back side of the second wafer using BHF or RCA; and
contacting the second back side of the second wafer with the first front side of the first wafer and then increasing a temperature to a range of 200° C. to 800° C.

16. The method according to claim 14, wherein the bonding by the medium of the paste layer comprises:
applying a dielectric paste to the first front side of the first wafer or the second back side of the second wafer, into a paste pattern comprising projections separated from one another or a stripe pattern;
contacting the first front side of the first wafer and the second back side of the second wafer with each other by the medium of the dielectric paste; and
hardening the dielectric paste.

17. The method according to claim 14, wherein the bonding by the medium of the polymer layer comprises:
coating a thermosetting polymer containing BCB, PAE, PBO or epoxy, to the first front side of the first wafer or the second back side of the second wafer;
baking the first wafer or the second wafer coated with the thermosetting polymer;
raising a temperature of the first wafer or the second wafer coated with the thermosetting polymer to a curing temperature of the polymer; and
pressing the first wafer and the second wafer with each other.

18. The method according to claim 11, wherein, after the forming, on the second front side of the second wafer, the circuit patterns which are connected to the through-silicon vias and the second bonding pads which are electrically connected to the circuit patterns, the method further comprises:
forming conductive projections which are connected to the second bonding pads of the second wafer.

19. The method according to claim 11, wherein, after the forming, on the second front side of the second wafer, the circuit patterns which are connected to the through-silicon vias and the second bonding pads which are electrically connected to the circuit patterns, the method further comprises:
preparing a third wafer having a third front side on which a semiconductor device, circuit patterns for applying electrical signals to the semiconductor device and third bonding pads connected to the circuit patterns are formed; and
bonding a third back side of the third wafer facing away from the third front side to the first back side of the first wafer.

20. The method according to claim 19, wherein, after the bonding of the third back side of the third wafer facing away from the third front side with the first back side of the first wafer, the method further comprises:
sawing the third wafer, the first wafer and the second wafer which are sequentially stacked and forming a third chip, a first chip and a second chip;
facing the third front side of the third wafer toward a substrate and flip-chip bonding the third front side of the third wafer to the substrate; and
wire bonding the second chip with the substrate.
